(19) United States
(12) Patent Application Publication
(10) Pub. No.: US 2021/0159154 A1
(43) Pub. Date: May 27, 2021

(54) SEMICONDUCTOR SUBSTRATE, SEMICONDUCTOR PACKAGE, METHOD OF MANUFACTURING THE SAME

(71) Applicant: Advanced Semiconductor Engineering, Inc., Kaohsiung (TW)

(72) Inventor: Wen Hung HUANG, Kaohsiung (TW)

(73) Assignee: Advanced Semiconductor Engineering, Inc., Kaohsiung (TW)

(21) Appl. No.: 16/691,295

(22) Filed: Nov. 21, 2019

(51) Int. Cl. H01L 23/498; H01L 23/31; H01L 21/768; H01L 23/00

(52) U.S. Cl. CPC H01L 23/49833; H01L 23/49861; H01L 23/3121; H01L 2224/02371; H01L 21/76805; H01L 24/05; H01L 21/76898

(57) ABSTRACT

A semiconductor substrate includes a first dielectric structure and a die. The first dielectric structure has a first surface and a second surface opposite to the first surface. The die is embedded within the first dielectric structure. The die includes an active surface facing the first surface of the first dielectric structure, a backside surface opposite to the active surface of the die and a metal layer disposed on the backside surface of the die. The metal layer is a recrystallized layer.

### BACKGROUND

### 1. Field of the Disclosure

The present disclosure relates to semiconductor substrates and semiconductor packages and methods of manufacturing the same.

### 2. Description of Related Art

A thinning process is generally carried out to reduce the thickness of a die before packaging. However, die warpage may occur after thinning. As shown in FIG. 1, a thinned die 1 is embedded within a dielectric layer 2 and via holes 3 and 4 are formed, e.g., by mechanical drilling, laser drilling or other processes (such as a photolithographic process), to make electrical connection of the die to another electronic device or circuit (not shown). However, since the die is warped due to thinning, the distance D₃ and D₄ from a top of the dielectric layer to the embedded die cannot remain uniform, which increases difficulty in the process for making via holes 3 and 4.

### SUMMARY

According to some embodiments of the present disclosure, a semiconductor substrate includes a first dielectric structure and a die. The first dielectric structure has a first surface and a second surface opposite to the first surface. The die is embedded within the first dielectric structure. The die includes an active surface facing the first surface of the first dielectric structure, a backside surface opposite to the active surface of the die and a metal layer disposed on the backside surface of the die. The metal layer is a recrystallized layer.

According to some embodiments of the present disclosure, a semiconductor package includes a semiconductor substrate, one or more electronic components and an encapsulant. The one or more electronic component is disposed on the semiconductor substrate. The encapsulant covers the electronic components and the semiconductor substrate. The semiconductor substrate includes a first dielectric structure and a die. The first dielectric structure has a first surface and a second surface opposite to the first surface. The die is embedded within the first dielectric structure. The die includes an active surface facing the first surface of the first dielectric structure, a backside surface opposite to the active surface of the die and a metal layer disposed on the backside surface of the die. The metal layer is a recrystallized layer.

According to some embodiments of the present disclosure, a method of manufacturing a semiconductor substrate includes: (a) providing a die having an active surface, a backside surface opposite to the active surface of the die and a recrystallized metal layer disposed on the backside surface of the die; (b) providing a first dielectric structure having a first surface and a second surface opposite to the first surface to cover the die wherein the recrystallized metal layer is exposed from the second surface of the first dielectric structure; and (c) forming a patterned conductive layer on the first surface of the first dielectric structure and extending to the active surface of the die.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of a semiconductor substrate including a warped die.

FIG. 2 is a cross-sectional view of a semiconductor substrate in accordance with some embodiments of the present disclosure.

FIG. 3 is a cross-sectional view of another semiconductor substrate in accordance with some embodiments of the present disclosure.

FIG. 4 is a cross-sectional view of another semiconductor substrate in accordance with some embodiments of the present disclosure.

FIG. 5 is a cross-sectional view of a semiconductor package in accordance with some embodiments of the present disclosure.

FIG. 6a, FIG. 6b, FIG. 6c, FIG. 6d, FIG. 6e, FIG. 7a, FIG. 7b, FIG. 7c, FIG. 7d, FIG. 7e and FIG. 7f illustrate various stages of a method for manufacturing a semiconductor substrate in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

The present disclosure describes techniques suitable for the manufacture of a semiconductor substrate with an embedded thin die. In some embodiments according to the present disclosure, a recrystallized metal layer is formed on the back surface of the die. The recrystallized metal layer has a relatively large specific weight as compared to the die and an enhanced mechanical strength due to recrystallization. The recrystallized metal layer can function as a die-warpage balance material and a heat dissipation material at the same time. Therefore, the semiconductor substrate according to the present disclosure may include a thinner die without the severe warpage that is found in the existing techniques.

FIG. 2 is a cross-sectional view of a semiconductor substrate in accordance with some embodiments of the present disclosure. As shown in FIG. 2, the semiconductor substrate 200 includes a first dielectric structure 11 and a die 12.

The first dielectric structure 11 has a first surface 11a and a second surface 11b opposite to the first surface 11a. The first dielectric structure may be made of a polymeric or a non-polymeric dielectric material. For example, the first dielectric structure 11 may include a flowable dielectric material in a hardened or semi-hardened state, such as a liquid crystal polymer, a resin with pre-impregnated fibers (e.g., a prepreg), Ajinomoto Buildup Film (ABF), a resin, an epoxy material, or other flowable dielectric material in a hardened or semi-hardened state.

The die 12 is embedded within the first dielectric structure 11. The die includes an active surface 12a facing the first surface of the first dielectric structure 11 and a backside surface 12b opposite to the active surface 12a of the die 12. In some embodiments, the die 12 includes a functional area 121 and a non-functional area 122. Integrated circuits and/or electronic devices are fabricated in the functional area 121 to provide the function of the die. The non-functional area 122 surrounds the functional area 121 and exposes the active surface 12a of the die 12.

The die 12 includes a metal layer 13. The metal layer 13 is disposed on and in direct contact with the backside surface 12b of the die 12. In some embodiments, the metal layer 13 is exposed from the second surface 11b of the first dielectric structure 11. The exposed surface 13b of the metal layer 13 may have a height higher than, substantially the same as or lower than a height of the second surface 11b of the first dielectric structure 11. In some embodiments as shown in FIG. 2, the exposed surface 13b of the metal layer 13 is coplanar with the second surface 11b of the first dielectric structure 11.

The metal layer 13 is a recrystallized layer. The metal layer 13 may be made of copper, nickel, silver, gold, iron, zinc, aluminum, tin, stainless steel, or other suitable metal or alloy. The recrystallized metal layer has a grain size greater than a grain size of a non-recrystallized metal layer made of same material. In some embodiments, the recrystallized metal layer has a grain size of 0.6 μm or more, 0.65 μm or more, 0.7 μm or more, 0.75 μm or more, 0.8 μm or more, 0.85 μm or more, or 0.9 μm or more. The recrystallized metal layer has a relatively large specific weight as compared to the die and an enhanced mechanical strength due to recrystallization. The recrystallized metal layer can function as a die-warpage balance material and also as a heat dissipation material. Therefore, by forming a recrystallized metal layer onto the backside surface of the die, a thinner die can be used without causing severe warpage.

As shown in FIG. 2, the semiconductor substrate may include a patterned conductive layer 14 disposed on the first surface 11a of the first dielectric structure 11 and extending to the active surface 12a of the die 12. In some embodiments, the patterned conductive layer 14 may be made of copper or other suitable metal or alloy. The patterned conductive layer 14 may include traces 142 and conductive vias 141. The conductive vias 141 penetrate the first dielectric structure 11 to contact the active surface 12a of the die 12.

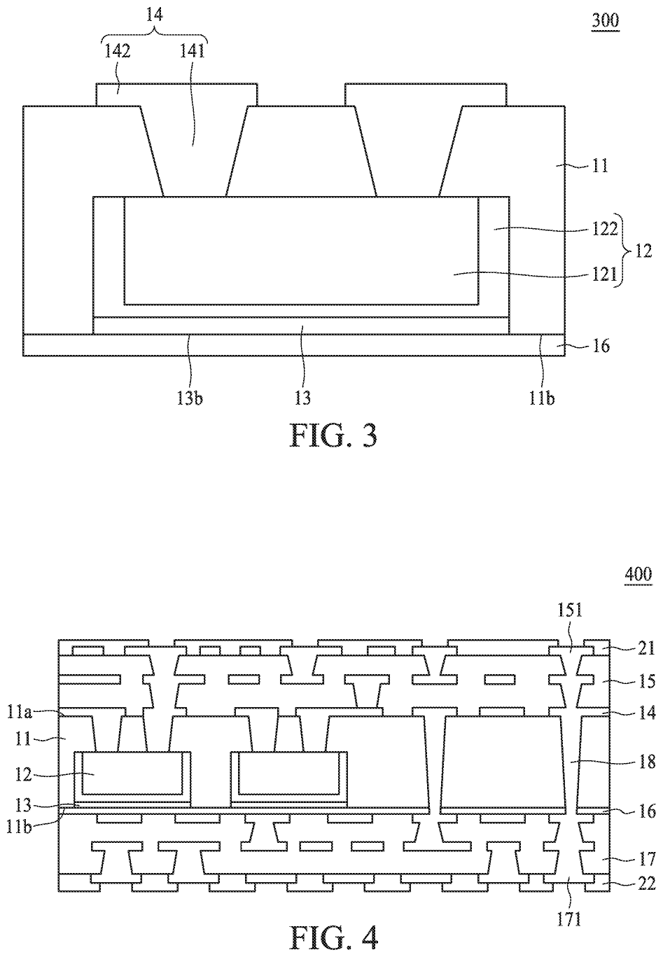

FIG. 3 is a cross-sectional view of another semiconductor substrate in accordance with some embodiments of the present disclosure. The semiconductor substrate 300 of FIG. 3 has a similar structure to that of the semiconductor substrate 200 of FIG. 2 except that the semiconductor substrate 300 includes a second dielectric structure 16.

The second dielectric structure 16 is attached to the second surface 11b of the first dielectric structure 11. As show in FIG. 3, the second dielectric structure 16 covers the first dielectric structure 11 and the die 12. In some embodiments, the second dielectric structure 16 is in direct contact with the second surface 11b of the first dielectric structure 11 and the surface 13b of the metal layer 13 exposed from the second surface 11b of the first dielectric structure 11. The second dielectric structure 16 may be made of the same material from which the first dielectric structure 11 are made in some embodiments. In some embodiments, the second dielectric structure 16 is made of Ajinomoto Buildup Film (ABF) or an ABF-like material.

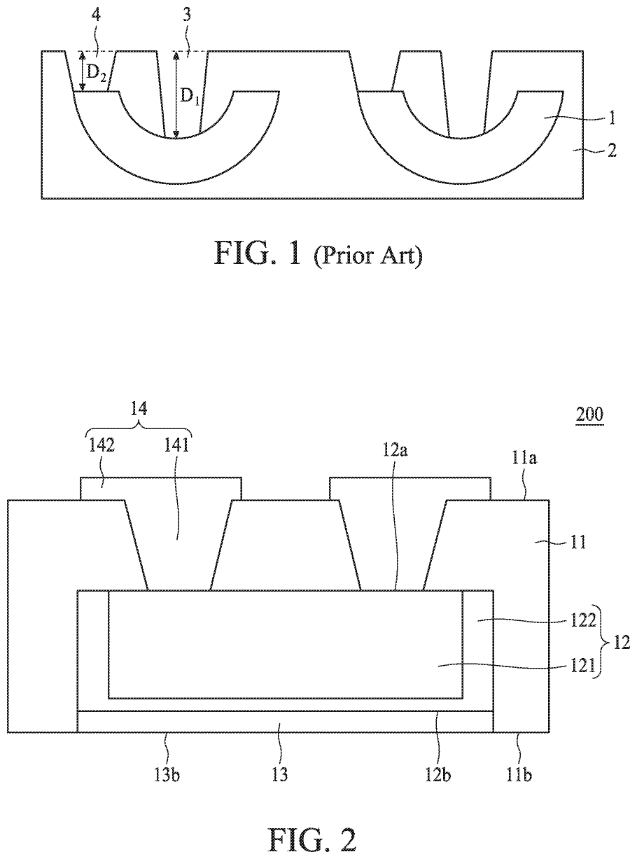

FIG. 4 is a cross-sectional view of another semiconductor substrate in accordance with some embodiments of the present disclosure. Similar to the semiconductor substrate 300 as illustrated in FIG. 3, the semiconductor substrate 400 of FIG. 4 includes a first dielectric structure 11, a die 12, a patterned conductive layer 14, and a second dielectric structure 16. The die 12 includes a metal layer 13 disposed on and in direct contact with the backside surface 12b of the die 12. The metal layer 13 is a recrystallized layer. Other details of the die 12, the patterned conductive layer 14, the metal layer 13 and the second dielectric structure 16 have been discussed above with respect to the embodiments illustrated in FIG. 1 or FIG. 2.

In some embodiments, the semiconductor substrate may further include an redistribution layer (RDL) structure 15 disposed on the patterned conductive layer 14 and the first surface 11a of the first dielectric structure 11 as shown in FIG. 4. The RDL structure 15 may be in direct contact with the patterned conductive layer 14 and the first surface 11a of the first dielectric structure 11.

In some embodiments, the semiconductor substrate may further include an redistribution layer (RDL) structure 17 disposed on the second surface 11b of the first dielectric structure 11. The RDL structure 17 may be in direct contact with the second surface 11b of the first dielectric structure 11 in some embodiments, or in direct contact with the second dielectric structure 16 disposed on the second surface 11b of the first dielectric structure 11 in some other embodiments, e.g., those illustrated in FIG. 4.

The RDL structure 15 and 17 may include one or more redistribution layers and insulation material(s) or dielectric material(s) (not denoted in FIG. 4) encapsulating the one or more redistribution layers. The insulation material(s) or dielectric material(s) may include organic material, solder mask, polyimide (PI), epoxy, Ajinomoto build-up film (ABF), molding compound, or a combination of two or more thereof.

The RDL structure 15 and 17 may include conductive trace(s), pad(s), contact(s), via(s) to electrically connect the one or more redistribution layers with each other, or electrically connect the RDL structure to the semiconductor component, or electrically connect the RDL structure to an external circuit or electronic component.

In some embodiments, the semiconductor substrate may further include a conductive member 18. The conductive member 18 may penetrate through the first dielectric structure 11 in some embodiments, or penetrate through the first dielectric structure 11 and the second dielectric structure 16 in some other embodiments, e.g., those illustrated in FIG. 4. The conductive member 18 electrically connects to a patterned conductive layer 14 disposed on the first surface 11a of the first dielectric structure 11. The conductive member 18 may further electrically connects to the RDL structure 17.

As shown in FIG. 4, the semiconductor substrate may further include a solder resist layer 21 or 22. The solder resist 21 is disposed on the RDL structure 15 and exposes the pads 151 of the RDL structure 15. The solder resist 22 is disposed on the RDL structure 17 and exposes the pads 171 of the RDL structure 17.

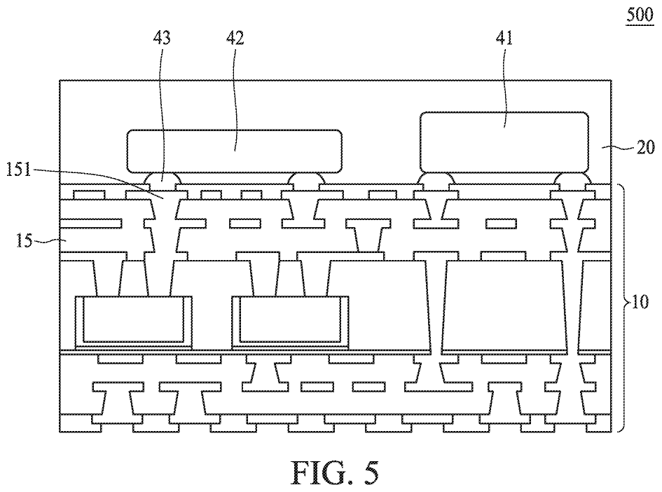

FIG. 5 is a cross-sectional view of a semiconductor package 500 in accordance with some embodiments of the present disclosure. The semiconductor package 500 includes a semiconductor substrate 10, one or more electronic components 41 and 42, and an encapsulant 20.

In some embodiments, the semiconductor substrate 10 may have a similar structure to that of the semiconductor substrate 200 illustrated in FIG. 2, the semiconductor substrate 300 illustrated in FIG. 3 or the semiconductor substrate 400 illustrated in FIG. 4. In the embodiments as shown in FIG. 5, the semiconductor substrate 10 has a similar structure to that of the semiconductor substrate 400 illustrated in FIG. 4.

The semiconductor package 500 includes one or more electronic components 41 and 42 disposed on the semiconductor substrate 10. The electronic components 41 and 42 may be an active component, e.g., a processor component, a switch component, an application specific IC (ASIC) or another active component, or a passive component e.g., a capacitor, a resistor, or the like. The electronic components 41 and 42 may be electrically connected to the semiconductor substrate, for example, by way of flip-chip or other techniques. In the embodiments as shown in FIG. 5, the electronic components 41 and 42 may be electrically connected to the pads 151 of the

RDL structure 15 of the semiconductor substrate 10 via solder balls 43.

The semiconductor package 500 includes an encapsulant 20. The encapsulant 20 covers or encapsulates the electronic components 41 and 42 and the semiconductor substrate 10. The encapsulant 20 may include insulation or dielectric material. In some embodiment, the encapsulant 20 be made of molding material that may include, for example, a Novolac-based resin, an epoxy-based resin, a silicone-based resin, or other another suitable encapsulant. Suitable fillers may also be included, such as powdered SiO₂.

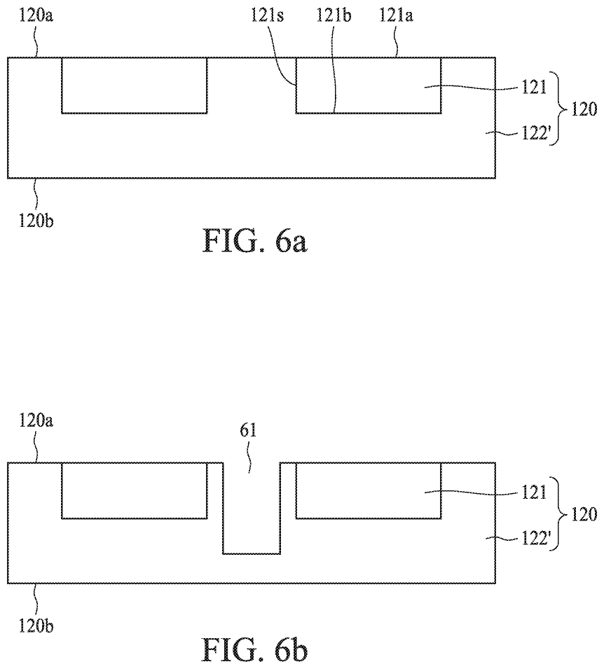

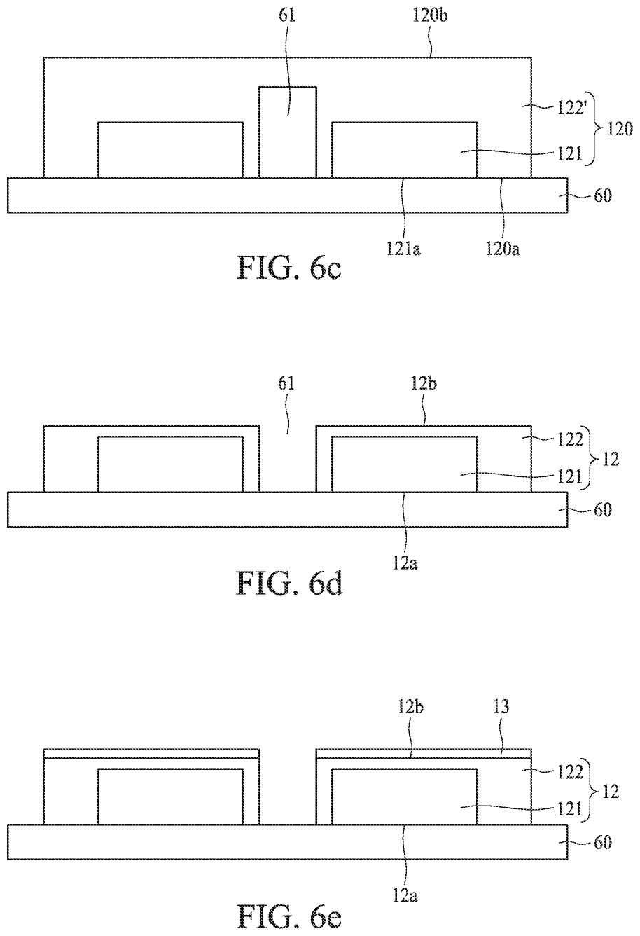

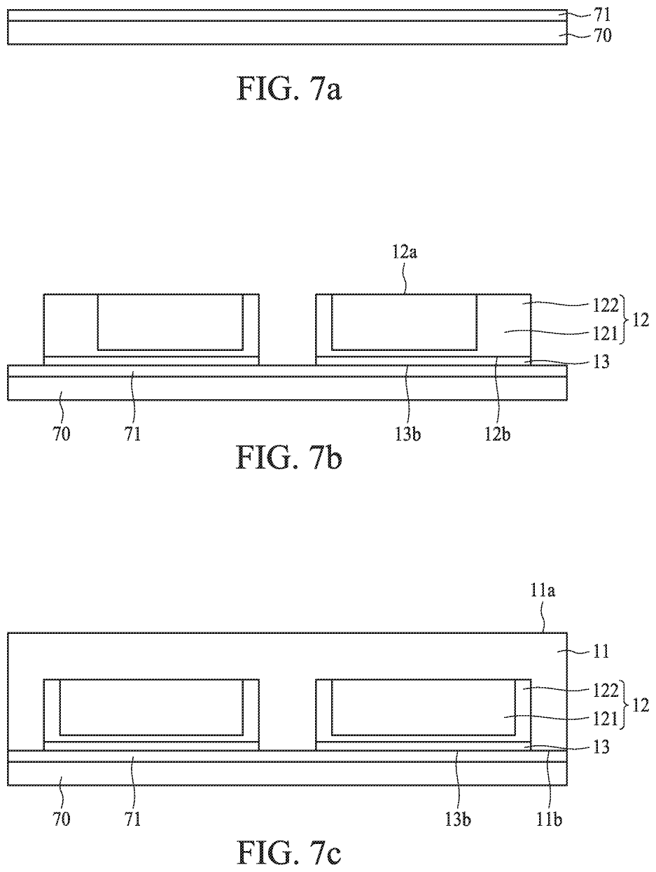

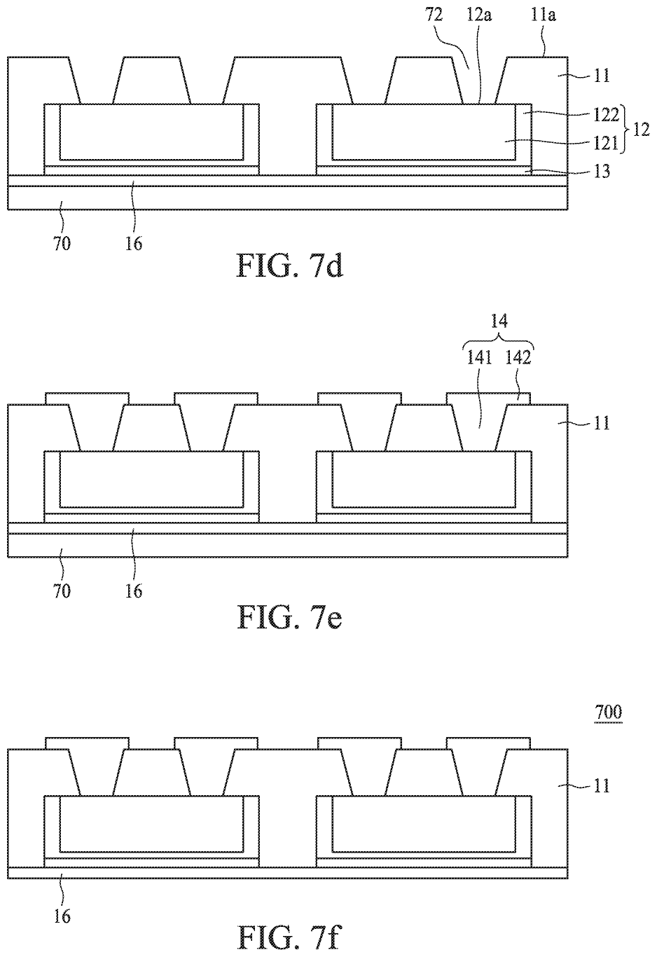

FIG. 6a, FIG. 6b, FIG. 6c, FIG. 6d, FIG. 6e, FIG. 7a, FIG. 7b, FIG. 7c, FIG. 7d, FIG. 7e and FIG. 7f illustrate various stages of a method for manufacturing a semiconductor substrate in accordance with some embodiments of the present disclosure.

The method for manufacturing a semiconductor substrate in accordance with some embodiments of the present disclosure includes: (a) providing a die having an active surface, a backside surface opposite the active surface of the die and a recrystallized metal layer disposed on the backside surface of the die; (b) providing a first dielectric structure having a first surface and a second surface opposite the first surface to cover the die wherein the recrystallized metal layer is exposed from the second surface of the first dielectric structure; and (c) forming a patterned conductive layer on the first surface of the first dielectric structure and extending to the active surface of the die.

FIG. 6a, FIG. 6b, FIG. 6c, FIG. 6d and FIG. 6e illustrate the method of providing a die 12 having an active surface 12a, a backside surface 12b opposite the active surface 12a of the die 12 and a recrystallized metal layer 13 disposed on the backside surface 12a of the die 12 in accordance with some embodiments of the present disclosure.

Referring to FIG. 6a, a wafer 120 (e.g., a silicon wafer) is provided. The wafer 120 has a front surface 120a and a back surface 120b opposite to the front surface 120a. The wafer 120 includes a plurality of functional areas 121 and a non-functional area 122′. The functional area 121 includes integrated circuits and/or electronic devices fabricated therein and provides the function of a die 12 (which will be fabricated as discussed below). A top surface 121a of the functional area 121 is exposed from the front surface 120a of the wafer 120. The non-functional area 122′ surrounds a lateral surface 121s and a bottom surface 121b of the functional area 121.

Referring to FIG. 6b, the wafer 120 is half-cut along the lateral surface 121s of each functional area 121 to from a groove 61 surrounding the functional area 121. A depth of the groove is greater than a thickness of the functional area 121.

Referring to FIG. 6c, after half-cut, the wafer 120 is attached to a carrier 60. The top surface 121a of the functional area 121 and the front surface 120a of the wafer faces the carrier 60.

Referring to FIG. 6d, a singulation process is carried out by grinding the back surface 120b to reduce the thickness of the non-functional area 122′ and expose the 61 groove. After singulation, a plurality of die 12 are formed. The die 12 includes an active surface 12a, a backside surface 12b opposite the active surface 12a of the die 12.

Referring to FIG. 6e, a recrystallized metal layer 13 is formed on the backside surface 12b of the die 12. The recrystallized metal layer 13 may be produced by forming a metal layer on the backside surface 12b of the die 12 and then recrystallizing the metal layer by annealing. After annealing, the grain size of the metal layer can be increased, for example, from 0.1 μm to 0.8 μm due to recrystallization. In some embodiments, the metal layer can be formed by, for example, sputtering a corresponding metal or alloy material (e.g., Cu) onto the backside surface 12b of the die 12. In some embodiments, an annealing process is carried out by heating the metal layer 13 to a temperature above a recrystallization temperature of the corresponding metal or alloy material, keeping at such temperature for a suitable time (e.g., 30 mins or more) and then slowly cooling down. In some embodiments, the annealing process is carried out by heating the metal layer 13 to a temperature of 250° C. or above, 280° C. or above, 300° C. or above, 350° C. or above, 350° C. or above, 400° C. or above, or 450° C. or above. After the metal layer 13 is recrystallized, the carrier 60 can be removed.

FIG. 7a, FIG. 7b and FIG. 7c illustrate the method of providing a first dielectric structure 11 to cover the die 12 in accordance with some embodiments of the present disclosure.

Referring to FIG. 7a, a carrier 70 is provided and a film 71 made of a dielectric material, such as ABF or ABF-like material, is applied onto a surface of the carrier 70.

Referring to FIG. 7b, a die 12 having an active surface 12a, a backside surface 12b opposite to the active surface 12a of the die 12 and a recrystallized metal layer 13 disposed on the backside surface 12a of the die 12 is provided. A surface 13b of the recrystallized metal layer 13, which faces away the active surface 12a of the die 12, is attached to the film 71. Since the recrystallized metal layer is applied to the backside surface of the die and effective to reduce die warpage, the die has a flatter surface than that in comparative embodiments. Therefore, the contact area of the die with the film can be increased so that the die is attached to the film more firmly, which prevents the die from falling off or becoming displaced.

Referring to FIG. 7c, a first dielectric structure 11 is applied to encapsulate the die 12. The first dielectric structure 11 may be made of a polymeric or a non-polymeric dielectric material as discussed above. The first dielectric structure 11 has a first surface 11a and a second surface 11b opposite to the first surface 11a. The surface 13b of the recrystallized metal layer 13 is exposed from and coplanar with the second surface 11b of the first dielectric structure 11. The film 71 constitutes the second dielectric structure 16 which have been discussed above. The second surface 11b of the first dielectric structure 11 is in contact with the film 71.

FIG. 7d and FIG. 7e illustrate the method of forming a patterned conductive layer 14 on the first surface 11a of the first dielectric structure 11 in accordance with some embodiments of the present disclosure.

Referring to FIG. 7d, a via hole 72 extending from the first surface 11a of the first dielectric structure 11 to the active surface 12a of the die 12 is formed in the first dielectric structure 11. The via hole 72 may be formed by various methods, e.g., lithography/etching, laser drilling, mechanical drilling or other suitable techniques.

Referring to FIG. 7e, a patterned conductive layer 14 is formed on the first surface 11a of the first dielectric structure 11 and in the via hole 72 by electroless plating or electroplating. The patterned conductive layer 14 includes traces 142 and conductive vias 141. The conductive vias 141 are formed in the via holes 72 and contact the active surface 12a of the die 12.

In FIG. 7f, the carrier 70 is removed and a semiconductor substrate 700 is obtained.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of embodiments of this disclosure are not deviated from by such an arrangement.

As used herein, the term “vertical” is used to refer to these upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor substrate, comprising:
a first dielectric structure having a first surface and a second surface opposite to the first surface; and
a die embedded within the first dielectric structure,
wherein the die comprises an active surface facing the first surface of the first dielectric structure, a backside surface opposite to the active surface of the die and a metal layer disposed on the backside surface of the die, and
wherein the metal layer is a recrystallized layer.

2. The semiconductor substrate of claim 1, further comprising a patterned conductive layer disposed on the first surface of the first dielectric structure and extending to the active surface of the die.

3. The semiconductor substrate of claim 1, wherein the metal layer is exposed from the second surface of the first dielectric structure.

4. The semiconductor substrate of claim 3, wherein the exposed surface of the metal layer is coplanar with the second surface of the first dielectric structure.

5. The semiconductor substrate of claim 2, further comprising an redistribution layer (RDL) structure disposed on the patterned conductive layer and the first surface of the first dielectric structure.

6. The semiconductor substrate of claim 1, further comprising a second dielectric structure attached to the second surface of the first dielectric structure.

7. The semiconductor substrate of claim 1, further comprising an redistribution layer (RDL) structure disposed on the second surface of the first dielectric structure.

8. The semiconductor substrate of claim 1, further comprising a conductive member penetrating through the first dielectric structure and electrically connecting to a patterned conductive layer disposed on the first surface of the first dielectric structure.

9. The semiconductor substrate of claim 1, further comprising a conductive member penetrating through the first dielectric structure and the second dielectric structure and electrically connecting to a patterned conductive layer disposed on the first surface of the first dielectric structure.

10. The semiconductor substrate of claim 1, wherein the recrystallized metal layer has a grain size greater than a grain size of a non- recrystallized metal layer made of same material.

11. The semiconductor substrate of claim 1, wherein the recrystallized metal layer has a grain size of 0.8 μm or more.

12. A semiconductor package, comprising:
a semiconductor substrate, comprising:
a first dielectric structure having a first surface and a second surface opposite to the first surface; and
a die embedded within the first dielectric structure,
wherein the die comprises an active surface facing the first surface of the first dielectric structure, a backside surface opposite to the active surface of the die and a metal layer disposed on the backside surface of the die, and
wherein the metal layer is a recrystallized layer;
one or more electronic components disposed on the semiconductor substrate; and
an encapsulant covering the one or more electronic components and the semiconductor substrate.

13. The semiconductor package of claim 12, wherein the semiconductor substrate further comprises a patterned conductive layer disposed on the first surface of the first dielectric structure and extending to the active surface of the die.

14. The semiconductor package of claim 12, wherein the metal layer is exposed from the second surface of the first dielectric structure.

15. The semiconductor package of claim 12, wherein the exposed surface of the metal layer is coplanar with the second surface of the first dielectric structure.

16. The semiconductor package of claim 12, wherein the semiconductor substrate further comprises a redistribution layer (RDL) structure disposed on a first surface of the first dielectric structure and in contact with the electronic components.

17. The semiconductor package of claim 12, wherein the semiconductor substrate further comprises a redistribution layer (RDL) structure disposed on the second surface of the first dielectric structure.

18-20. (canceled)

21. The semiconductor substrate of claim 6, wherein the second dielectric structure covers the first dielectric structure and the die.

22. The semiconductor substrate of claim 6, wherein the second dielectric structure contacts the metal layer.

23. The semiconductor substrate of claim 1, wherein the metal layer has a relatively large specific weight as compared to the die.
